(19) United States
(12) Patent Application Publication
(10) Pub. No.: US 2021/0305077 A1
(43) Pub. Date: Sep. 30, 2021

(54) DEVICE FOR SUPPORTING SUBSTRATE HAVING THERMAL EXPANSION COEFFICIENT

(71) Applicant: Tokyo Electron Limited, Tokyo (JP)

(72) Inventor: Daisuke HAYASHI, Nirasaki City (JP)

(21) Appl. No.: 17/192,081

(22) Filed: Mar. 4, 2021

(30) Foreign Application Priority Data
Mar. 31, 2020 (JP) 2020-062917

(51) Int. Cl. H01L 21/683; H01L 21/67; H01J 37/32

(52) U.S. Cl. CPC H01L 21/6833; H01L 21/67069; H01J 2237/2005; H01J 2237/2007; H01J 37/32715

(57) ABSTRACT

A device for supporting a substrate having a thermal expansion coefficient, includes: a base; an electrostatic chuck disposed on the base and having a substrate supporting region, the electrostatic chuck having a thermal expansion coefficient different from the thermal expansion coefficient of the substrate; and an annular elastic seal disposed on the substrate supporting region so as to make contact with the substrate supported on the substrate supporting region.

### CROSS-REFERENCE TO RELATED APPLICATION

This application is based upon and claims the benefit of priority from Japanese Patent Application No. 2020-062917, filed on Mar. 31, 2020, the entire contents of which are incorporated herein by reference.

### TECHNICAL FIELD

The present disclosure relates to a device for supporting a substrate having a thermal expansion coefficient.

### BACKGROUND

Conventionally, there is known a plasma processing apparatus that performs plasma processing such as etching or the like on a substrate such as a semiconductor wafer (hereinafter referred to as “wafer”) or the like by using plasma. Such a plasma processing apparatus includes, for example, a stage that serves as an electrode inside a processing container capable of forming a vacuum space. The plasma processing apparatus performs plasma processing on a substrate placed on the stage. Further, an electrostatic chuck for holding the substrate as a target object is provided on the stage. For example, the plasma processing apparatus applies a voltage to the electrostatic chuck during the plasma processing period and attracts the substrate by the electrostatic force of the electrostatic chuck. As a result, the substrate is held on the upper surface of the electrostatic chuck.

### PRIOR ART DOCUMENT

### Patent Document

Patent Document 1: Japanese Laid-open Publication No. 2014-195047

### SUMMARY

According to one embodiment of the present disclosure, a device for supporting a substrate having a thermal expansion coefficient, includes: a base; an electrostatic chuck disposed on the base and having a substrate supporting region, the electrostatic chuck having a thermal expansion coefficient different from the thermal expansion coefficient of the substrate; and an annular elastic seal disposed on the substrate supporting region so as to make contact with the substrate supported on the substrate supporting region.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a schematic cross-sectional view showing an example of a configuration of a plasma processing apparatus according to an embodiment.

FIG. 2 is a schematic cross-sectional view showing an example of a stage in the plasma processing apparatus of FIG. 1.

FIG. 3 is a diagram schematically showing an example of a contact portion between a holding surface (or supporting surface) of an electrostatic chuck and a wafer W.

FIG. 4 is a diagram for explaining deformation of an elastic seal according to an embodiment.

FIG. 5 is a diagram showing an example in which a protective wall is formed on the electrostatic chuck.

FIG. 6 is a diagram showing an example in which an elastic seal is provided around a lower surface of the electrostatic chuck provided on a lower surface of a cooling plate.

FIG. 7 is a diagram showing an example in which an elastic seal is provided around an upper surface of a flange portion of the electrostatic chuck.

### DETAILED DESCRIPTION

Hereinafter, a substrate processing apparatus and a holding (or supporting) device according to an embodiment will be described in detail with reference to the drawings. The substrate processing apparatus includes a plasma processing apparatus, a heat treatment apparatus, and the like. In the present embodiment, a case where the substrate processing apparatus is a plasma processing apparatus that performs plasma etching on a substrate will be described as an example. In addition, the same or corresponding parts in each drawing will be designated by like reference numerals. The substrate processing apparatus disclosed herein is not limited by the present embodiment. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the plasma processing apparatus, the temperatures of the substrate and the stage change due to the heat inputted from plasma during the plasma processing period. Further, the temperature of the substrate held on the upper surface of the electrostatic chuck is controlled by changing the temperature of the stage by a heater provided in the stage according to a recipe of plasma processing. When the temperatures of the substrate and the stage are changed in a state in which the substrate is held on the upper surface of the electrostatic chuck, a difference in thermal expansion between the substrate and the electrostatic chuck occurs due to a difference in thermal expansion coefficients between the substrate and the electrostatic chuck. In the plasma processing apparatus, when there is a difference in thermal expansion between the substrate and the electrostatic chuck, a contact portion between the upper surface of the electrostatic chuck, which is a holding surface (or supporting surface), and the substrate, which is a target object, may rub against each other to generate particles, which may scatter in a space inside the processing container. If the particles scattered in the space inside the processing container adhere to the substrate, they may cause a defect in the substrate.

Therefore, it is expected to suppress the scattering of particles generated due to the rubbing between the holding surface (or supporting surface) and the target object.

### [Configuration of Plasma Processing Apparatus]

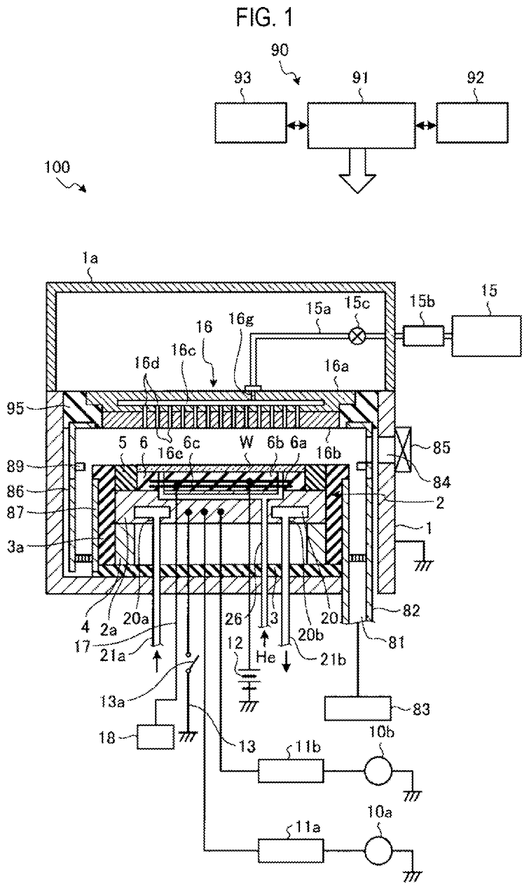

An example of the plasma processing apparatus according to an embodiment will be described. FIG. 1 is a schematic cross-sectional view showing an example of a configuration of a plasma processing apparatus 100 according to the embodiment. The plasma processing apparatus 100 includes a processing container 1 which has an airtight configuration and has an electrically ground potential. The processing container 1 has a cylindrical shape and is made of, for example, aluminum or the like. A processing space in which plasma is generated is formed inside the processing container 1. A stage 2 for horizontally supporting a semiconductor wafer (hereinafter simply referred to as “wafer”) W, which is a substrate, is provided inside the processing container 1.

The stage 2 includes a base 2a and an electrostatic chuck (ESC) 6. The base 2a is made of a conductive metal, for example, aluminum or the like, and has a function as a lower electrode. The electrostatic chuck 6 has a function of electrostatically attracting the wafer W. The electrostatic chuck 6 is bonded to the base 2a via a bonding layer (not shown). The stage 2 is supported by a support table 4. The support table 4 is supported by a support member 3 made of a dielectric material such as, for example, quartz or the like. Further, an edge ring 5 such as a focus ring made of, for example, monocrystalline silicon, is provided on an upper outer periphery of the stage 2. Moreover, inside the processing container 1, a cylindrical inner wall member 3a made of a dielectric material such as, for example, quartz or ceramic, is provided so as to surround the stage 2 and the support table 4.

One or more radio frequency (RF) power sources are connected to the base 2a. In one example, a first RF power source 10a is connected to the base 2a via a first matcher 11a, and a second RF power source 10b is connected to the base 2a via a second matcher 11b. The first RF power source 10a is a power source that generates RF power for plasma generation. The first RF power source 10a supplies RF power having a predetermined frequency in a range of 27 to 100 MHz, for example, a frequency of 40 MHz, to the base 2a of the stage 2 during plasma processing. The second RF power source 10b is a power source that generates RF power for ion attraction (for bias). During plasma processing, the second RF power source 10b supplies RF power having a predetermined frequency in a range of 400 kHz to 13.56 MHz, which is lower than that of the first RF power source 10a, for example, RF power having a frequency of 3 MHz, to the base 2a of the stage 2. As described above, the stage 2 is configured to be able to apply two RF powers having different frequencies from the first RF power source 10a and the second RF power source 10b. Meanwhile, above the stage 2, a shower head 16 having a function as an upper electrode is provided so as to face the stage 2 in parallel. The shower head 16 and the stage 2 function as a pair of electrodes (upper electrode and lower electrode). The first RF power source 10a may be connected to the shower head 16 via the first matcher 11a.

Further, the base 2a is electrically grounded via a wiring 13. A switch 13a such as a relay switch or the like is provided in the wiring 13. The base 2a can be electrically switched between a grounded state and a floating state by turning the switch 13a on and off.

The electrostatic chuck 6 is formed in a disk shape having a flat upper surface. The electrostatic chuck 6 is configured such that an electrode 6a is interposed between insulators 6b. A DC power source 12 is connected to the electrode 6a. The electrostatic chuck 6 attracts the wafer W by the Coulomb force (electrostatic force) generated by applying a DC voltage from the DC power source 12 to the electrode 6a. As a result, the wafer W is held on the upper surface of the electrostatic chuck 6. That is, the upper surface of the electrostatic chuck 6 is an example of a first holding surface (or supporting surface) for holding (or supporting) the wafer W.

The electrostatic chuck 6 may be provided with a heater 6c arranged below the electrode 6a in the insulators 6b. The heater 6c is connected to a heater power source 18 via a wiring 17. The heater power source 18 supplies an adjusted power to the heater 6c under the control of a controller (not shown). As a result, the heat generated by the heater 6c is controlled, and the temperature of the wafer W arranged on the electrostatic chuck 6 is adjusted.

A flow path 20 is formed inside the base 2a. A refrigerant inlet pipe 21a is connected to one end of the flow path 20. A refrigerant outlet pipe 21b is connected to the other end of the flow path 20. The refrigerant inlet pipe 21a and the refrigerant outlet pipe 21b are connected to a chiller unit (not shown). The flow path 20 is located below the wafer W and functions to absorb the heat of the wafer W. The plasma processing apparatus 100 is configured to be able to control the temperature of the stage 2 to a predetermined temperature by circulating a refrigerant, such as cooling water or the like or an organic solvent such as Garden or the like, from the chiller unit into the flow path 20 via the refrigerant inlet pipe 21a and the refrigerant outlet pipe 21b. Further, a gas supply pipe 26 for supplying a heat transfer gas such as helium gas or the like is provided on the back surface of the wafer W so as to penetrate the stage 2 and the like. The gas supply pipe 26 is connected to a gas source (not shown). With these configurations, the plasma processing apparatus 100 controls the temperature of the wafer W, which is attracted and held by the electrostatic chuck 6 on the upper surface of the stage 2, to a predetermined temperature.

The shower head 16 is provided on a top wall portion of the processing container 1. The shower head 16 includes a cooling plate 16a and an upper top plate 16b constituting an electrode plate. The shower head 16 is supported on the upper portion of the processing container 1 via an insulating member 95. The cooling plate 16a is made of a conductive material, for example, aluminum having an anodized surface, and is configured so that the upper top plate 16b can be detachably supported under the cooling plate 16a.

The cooling plate 16a is provided with a gas diffusion chamber 16c therein. Further, the cooling plate 16a has a large number of gas passage holes 16d formed under the gas diffusion chamber 16c. The upper top plate 16b is provided so that gas introduction holes 16e penetrating the upper top plate 16b in the thickness direction thereof overlap the gas passage holes 16d. With such a configuration, a processing gas supplied to the gas diffusion chamber 16c is dispersed and supplied into the processing container 1 in the form of a shower through the gas passage holes 16d and the gas introduction holes 16e.

The cooling plate 16a has a gas introduction port 16g for introducing the processing gas into the gas diffusion chamber 16c. One end of a gas supply pipe 15a is connected to the gas introduction port 16g. A processing gas source 15 for supplying a processing gas is connected to the other end of the gas supply pipe 15a. In the gas supply pipe 15a, a mass flow controller (MFC) 15b and an opening/closing valve 15c are provided sequentially from the upstream side. A processing gas for plasma etching is supplied to the gas diffusion chamber 16c from the processing gas source 15 via the gas supply pipe 15a. The processing gas is dispersed and supplied from the gas diffusion chamber 16c into the processing container 1 in the form of a shower through the gas passage holes 16d and the gas introduction holes 16e.

Further, the cooling plate 16a includes a cooling mechanism configured to cool the upper top plate 16b. The cooling mechanism has a spiral or annular refrigerant flow path extending in the circumferential direction, and supplies a low-temperature refrigerant from the chiller unit to the refrigerant flow path in a circulating manner via a cooling pipe. As the refrigerant, for example, cooling water, Garden (registered trademark), or the like is used. The upper top plate 16b becomes hot due to the heat input from the plasma. In the plasma processing apparatus 100 according to the embodiment, the upper top plate 16b is cooled by bringing the upper top plate 16b and the cooling plate 16a into close contact with each other and dissipating the heat of the upper top plate 16b to the cooling plate 16a.

A cylindrical ground conductor 1a is provided so as to extend above a height position of the shower head 16 from the side wall of the processing container 1. The cylindrical ground conductor 1a has a top wall at the top thereof.

An exhaust port 81 is formed at the bottom of the processing container 1. An exhaust device 83 is connected to the exhaust port 81 via an exhaust pipe 82. The exhaust device 83 depressurizes the inside of the processing container 1 to a predetermined degree of vacuum by operating a vacuum pump. On the other hand, a loading/unloading port 84 for the wafer W is provided on the side wall of the processing container 1. A gate valve 85 that opens and closes the loading/unloading port 84 is provided in the loading/unloading port 84.

The operation of the plasma processing apparatus 100 having the above configuration is controlled overall by a controller 90. The controller 90 includes a process controller 91 provided with a CPU and configured to control each part of the plasma processing apparatus 100, a user interface 92, and a storage 93.

The user interface 92 includes a keyboard for a process manager to input commands for managing the plasma processing apparatus 100, a display for visually displaying the operating status of the plasma processing apparatus 100, and the like.

The storage 93 stores recipes in which a control program (software) for realizing various processes executed by the plasma processing apparatus 100 under the control of the process controller 91, processing condition data, and the like are included. If necessary, an arbitrary recipe is called from the storage 93 by an instruction from the user interface 92 or the like and executed by the process controller 91, whereby a desired process is performed by the plasma processing apparatus 100 under the control of the process controller 91.

### [Configuration of Main Part of Stage]

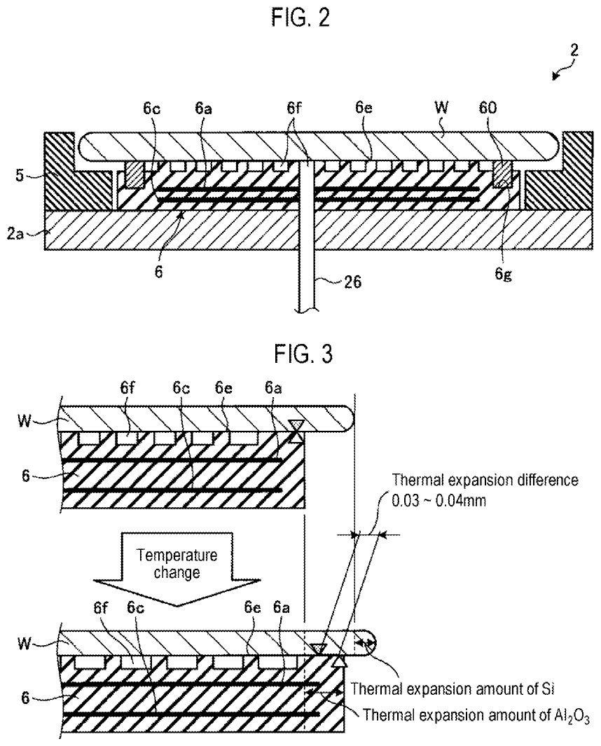

Next, a configuration of a main part of the stage 2 will be described with reference to FIG. 2. FIG. 2 is a schematic cross-sectional view showing an example of the stage 2 of the plasma processing apparatus 100 of FIG. 1. As described above, the stage 2 includes the base 2a and the electrostatic chuck 6, and the wafer W, which is a target object, is held on the upper surface of the electrostatic chuck 6. That is, the upper surface of the electrostatic chuck 6 constitutes a substrate holding (or supporting) region which has a circular shape in a plan view and has a plurality of holding surfaces (or supporting surfaces) 6e on which the wafer W is held. The plurality of holding surfaces (or supporting surfaces) 6e are discretely arranged in the substrate holding (or supporting) region. The electrostatic chuck 6 has a thermal expansion coefficient different from that of the wafer W. For example, when the electrostatic chuck 6 is made of alumina (Al₂O₃) and the wafer W is made of silicon (Si), the thermal expansion coefficient of the electrostatic chuck 6 is about 8, whereas the thermal expansion coefficient of the wafer W is about 3.5. The electrostatic chuck 6 is an example of a holder.

A plurality of dots (convex portions) may be formed on the holding surface (or supporting surface) 6e of the electrostatic chuck 6. In this case, the gas supply pipe 26, which penetrates the electrostatic chuck 6 and the base 2a and has an end portion (gas hole) arranged on the holding surface (or supporting surface) 6e, is formed in the electrostatic chuck 6 and the base 2a. In such a configuration, a heat transfer gas can be supplied to a space 6f located between the holding surface (or supporting surface) 6e of the electrostatic chuck 6 and the back surface of the wafer W during the plasma processing on the wafer W.

An elastic seal 60 is provided around the holding surface (or supporting surface) 6e of the electrostatic chuck 6. The elastic seal 60 has an annular shape (annular elastic seal) and comes into contact with the back surface of the wafer W held by the holding surface (or supporting surface) 6e to seal the outer circumference of the contact portion between the electrostatic chuck 6 and the wafer W. The elastic seal 60 is arranged so as to be deformable in such a direction that the elastic seal 60 absorbs the difference in thermal expansion between the wafer W and the electrostatic chuck 6. In the case of the present embodiment, the elastic seal 60 is arranged so as to be deformable radially inward with respect to the center of the holding surface (or supporting surface) 6e.

As described above, in the plasma processing apparatus 100, particles may be generated at the contact portion between the holding surface (or supporting surface) 6e of the electrostatic chuck 6 and the back surface of the wafer W due to the difference in thermal expansion between the wafer W and the electrostatic chuck 6.

FIG. 3 is a diagram schematically showing an example of the contact portion between the holding surface (or supporting surface) 6e of the electrostatic chuck 6 and the wafer W. As shown in FIG. 3, the wafer W is held on the holding surface (or supporting surface) 6e of the electrostatic chuck 6. That is, the wafer W is held on the holding surface (or supporting surface) 6e by the Coulomb force (electrostatic force) generated by applying a DC voltage to the electrode 6a of the electrostatic chuck 6. In the plasma processing apparatus 100, when the temperatures of the wafer W and the electrostatic chuck 6 are changed in a state in which the wafer W is held on the holding surface (or supporting surface) 6e of the electrostatic chuck 6, a difference (thermal expansion difference) between the thermal expansion amount of the wafer W and the thermal expansion amount of the electrostatic chuck 6 is generated due to the difference in the thermal expansion coefficients between the wafer W and the electrostatic chuck 6. The upper side in FIG. 3 shows a state of the wafer W and the electrostatic chuck 6 before the temperatures of the wafer W and the electrostatic chuck 6 are changed, and the lower side in FIG. 3 shows a state of the wafer W and the electrostatic chuck 6 after the temperatures of the wafer W and the electrostatic chuck 6 are changed. For example, when the electrostatic chuck 6 is made of alumina (Al₂O₃) and the wafer W is made of silicon (Si), the thermal expansion coefficient (about 8) of the electrostatic chuck 6 is larger than the thermal expansion coefficient (about 3.5) of the wafer W. Therefore, each of the wafer W and the electrostatic chuck 6 is thermally expanded in response to the respective temperature change, and a difference in thermal expansion between the wafer W and the electrostatic chuck 6 is generated in the radial direction of the wafer W. When the difference in thermal expansion between the wafer W and the electrostatic chuck 6 is generated, the contact portion between the holding surface (or supporting surface) 6e of the electrostatic chuck 6 and the wafer W may rub against each other to generate particles, which may be scattered in the space inside the processing container 1. If the particles scattered in the processing container 1 adhere to the wafer W, they may cause a defect in the wafer W.

Therefore, as shown in FIG. 2, in the plasma processing apparatus 100 according to the embodiment, the elastic seal 60, which is deformable in such a direction that the elastic seal 60 absorbs the difference in thermal expansion between the wafer W and the electrostatic chuck 6, is arranged around the holding surface (or supporting surface) 6e of the electrostatic chuck 6 so as to make contact with the outer edge of the back surface of the wafer W.

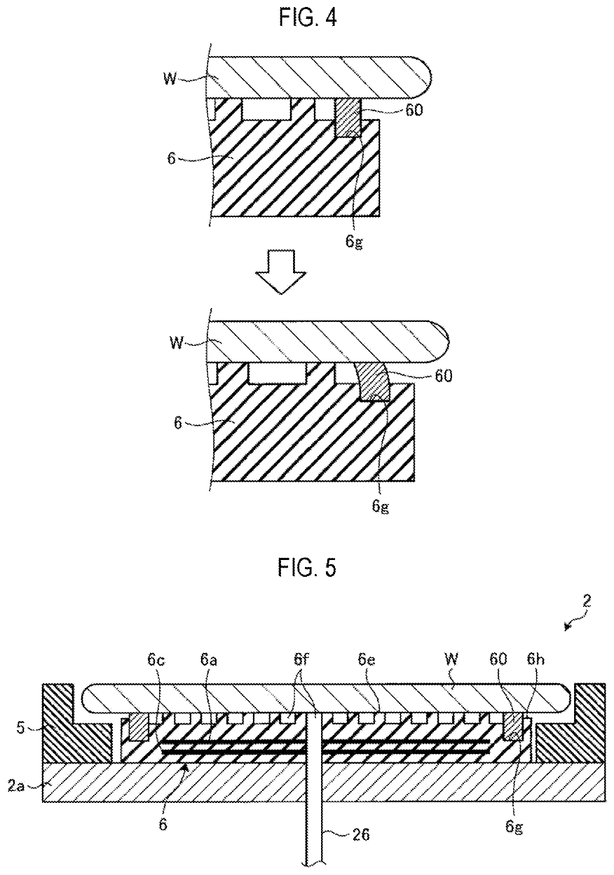

Here, the deformation of the elastic seal 60 will be described with reference to FIG. 4. The upper side in FIG. 4 shows a state of the elastic seal 60 before the temperatures of the wafer W and the electrostatic chuck 6 are changed, and the lower side in FIG. 4 shows a state of the elastic seal 60 after the temperatures of the wafer W and the electrostatic chuck 6 are changed. In FIG. 4, it is assumed that the electrostatic chuck 6 is made of alumina (Al₂O₃) and the wafer W is made of silicon (Si). In this case, since the thermal expansion coefficient of the electrostatic chuck 6 is larger than the thermal expansion coefficient of the wafer W, a difference in thermal expansion between the wafer W and the electrostatic chuck 6 is generated in the radial direction of the wafer W according to the temperature change of each of the wafer W and the electrostatic chuck 6. At this time, the upper end side (free end side) of the elastic seal 60 is elastically deformed in such a direction in which the elastic seal 60 absorbs the thermal expansion difference between the wafer W and the electrostatic chuck 6. That is, since the thermal expansion coefficient of the electrostatic chuck 6 is larger than the thermal expansion coefficient of the wafer W, the elastic seal 60 is bent radially inward of wafer W while maintaining contact with the back surface of the wafer W as shown on the lower side in FIG. 4. By elastically deforming the elastic seal 60 in the direction in which the elastic seal 60 absorbs the thermal expansion difference between the wafer W and the electrostatic chuck 6 in this manner, the close contact between the elastic seal 60 and the wafer W is maintained. As a result, the plasma processing apparatus 100 can seal the particles generated due to the rubbing between the back surface of the wafer W and the electrostatic chuck 6 through the use of the elastic seal 60, and can suppress the scattering of the particles into the processing container 1.

In one example, a portion of the lower end (fixed end side) of the elastic seal 60 is accommodated in a recess 6g formed around the holding surface (or supporting surface) 6e of the electrostatic chuck 6. As a result, it is possible to suppress separation of the elastic seal 60 due to the rubbing against the wafer W.

Further, the elastic seal 60 is arranged so that an inner surface of the elastic seal 60 is separated from an outer surface of the portion of the electrostatic chuck 6 where the holding surface (or supporting surface) 6e is formed. For example, when the holding surface (or supporting surface) 6e has a plurality of dots, the elastic seal 60 is arranged so as to be separated from the outer surfaces of the dots located on the outermost periphery. As a result, the deformation of the elastic seal 60 can be absorbed by the gap between the inner surface of the elastic seal 60 and the outer surface of the electrostatic chuck 6 facing the inner surface, and the close contact between the elastic seal 60 and the wafer W can be maintained.

Further, in one example, the upper end of the elastic seal 60 protrudes from the holding surface (or supporting surface) 6e when the wafer W is not held on the holding surface (or supporting surface) 6e. On the other hand, when the wafer W is held on the holding surface (or supporting surface) 6e, the elastic seal 60 is compressed until its upper end surface has the same height as the holding surface (or supporting surface) 6e. As a result, a degree of close contact between the elastic seal 60 and the wafer W can be increased to improve the sealing property.

As the material of the elastic seal 60, a fluorine resin, a silicon resin or the like may be used. Among them, a material having a plasma resistance and having such a friction coefficient that does not cause rubbing against the wafer W is preferable.

As described above, the stage 2 according to the embodiment includes the electrostatic chuck 6 and the elastic seal 60. The electrostatic chuck 6 includes the holding surface (or supporting surface) 6e which makes contact with the back surface of the wafer W to hold or support the wafer W, and has a thermal expansion coefficient which is different from the thermal expansion coefficient of the wafer W. The elastic seal 60 is arranged around the holding surface (or supporting surface) 6e of the electrostatic chuck 6 so as to make contact with the back surface of the wafer W. As a result, it is possible to suppress the scattering of particles generated due to the rubbing between the holding surface (or supporting surface) 6e and the back surface of the wafer W.

It should be noted that the embodiment disclosed herein is exemplary in all respects and is not restrictive. The above-described embodiment may be omitted, replaced, or changed in various forms without departing from the scope of the appended claims and the gist thereof.

For example, the electrostatic chuck 6 may include a protective wall that partially protects the outer surface of the elastic seal 60. FIG. 5 is a diagram showing an example in which the protective wall is formed on the electrostatic chuck 6. The electrostatic chuck 6 shown in FIG. 5 has a protective wall 6h formed along the outer surface of the elastic seal 60 and configured to protect the outer surface of the elastic seal 60 without making contact with the back surface of the wafer W. By forming the protective wall 6h on the electrostatic chuck 6, it is possible to reduce the damage to the outer surface of the elastic seal 60 which may be caused by the plasma generated in the processing container 1 during the plasma processing period. Further, since the protective wall 6h does not come into contact with the back surface of the wafer W, it is possible to avoid the generation of particles due to the rubbing between the protective wall 6h and the back surface of the wafer W.

Further, the elastic seal 60 of the embodiment can be applied to a contact portion between two members other than the wafer W and the electrostatic chuck 6. For example, when an electrostatic chuck is provided on the lower surface of the cooling plate 16a of the shower head 16, the upper top plate 16b, which is a target object, is held on the lower surface of the electrostatic chuck. Under this circumstance, when the temperatures of the upper top plate 16b and the electrostatic chuck are changed due to the heating by plasma or the like, particles may be generated at the contact portion between the lower surface of the electrostatic chuck and the upper top plate 16b due to the difference in thermal expansion coefficients between the upper top plate 16b and the electrostatic chuck. Therefore, an elastic seal 60 may be provided around the lower surface of the electrostatic chuck, which is provided on the lower surface of the cooling plate 16a.

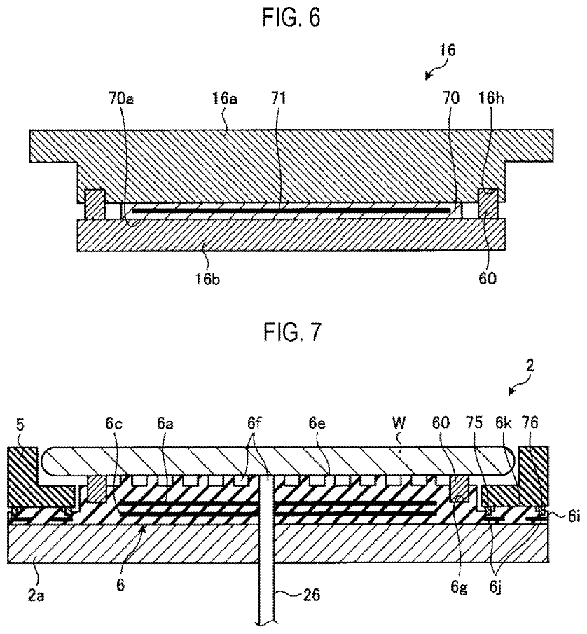

FIG. 6 is a diagram showing an example in which the elastic seal 60 is provided around the lower surface of the electrostatic chuck, which is provided on the lower surface of the cooling plate 16a. An electrostatic chuck 70 is provided on the lower surface of the cooling plate 16a shown in FIG. 6. The electrostatic chuck 70 has a disk shape with flat upper and lower surfaces, and is configured by interposing an electrode 71 between insulators. A DC power source is connected to the electrode 71. The electrostatic chuck 70 attracts the upper top plate 16b by the Coulomb force (electrostatic force) generated by applying a DC voltage from the DC power source to the electrode 71. As a result, the upper top plate 16b, which is a target object, is held on the lower surface of the electrostatic chuck 70. That is, the lower surface of the electrostatic chuck 70 constitutes a holding surface (or supporting surface) 70a on which the upper top plate 16b is held. The elastic seal 60 is provided around the holding surface (or supporting surface) 70a of the electrostatic chuck 70. The elastic seal 60 has an annular shape surrounding the electrostatic chuck 70, and comes into contact with the upper top plate 16b held by the holding surface (or supporting surface) 70a to seal the contact portion between the electrostatic chuck 70 and the upper top plate 16b. The elastic seal 60 has elasticity so as to be deformed in such a direction that the elastic seal 60 absorbs the difference in thermal expansion between the upper top plate 16b and the electrostatic chuck 70. As a result, it is possible to suppress the scattering of particles generated due to the rubbing between the holding surface (or supporting surface) 70a and the upper top plate 16b. Further, a recess 16h is formed on the lower surface of the cooling plate 16a around the electrostatic chuck 70, and a portion of the elastic seal 60 is accommodated in the recess 16h. As a result, it is possible to prevent separation of the elastic seal 60 due to the rubbing against the upper top plate 16b. The chuck for holding (or supporting) the upper top plate 16b on the cooling plate 16a is not limited to the electrostatic chuck, and a chuck for mechanically holding (or supporting) the upper top plate 16b may be used.

Further, when the edge ring 5 is electrostatically attracted to the electrostatic chuck 6, another elastic seal may be applied to the contact portion between the edge ring 5 and the electrostatic chuck 6. For example, a region for holding (or supporting) the edge ring may be provided radially outward of the electrostatic chuck 6, and the edge ring 5 may be held on the upper surface of this region. The region for holding (or supporting) the edge ring 5 may be formed integrally with the electrostatic chuck 6 or may be formed separately from the electrostatic chuck 6. In one example, the flange portion formed at the lower end of the electrostatic chuck 6 may be used as a region for holding (or supporting) the edge ring 5. In this case, the edge ring 5, which is a target object, is held on the upper surface of the flange portion. When the temperatures of the edge ring 5 and the electrostatic chuck 6 are changed due to the heat input by plasma or the like, particles may be generated at the contact portion between the upper surface of the flange portion of the electrostatic chuck 6 and the edge ring 5 due to the difference in thermal expansion coefficients between the edge ring 5 and the electrostatic chuck 6. Thus, an elastic seal may be provided around the upper surface of the flange portion of the electrostatic chuck 6.

FIG. 7 is a diagram showing an example in which elastic seals 75 and 76 are provided around the upper surface of the flange portion of the electrostatic chuck 6. On a lower end of the electrostatic chuck 6 shown in FIG. 7, a flange portion 6i protruding radially outward of the electrostatic chuck 6 is formed. A convex portion on which the edge ring 5 is arranged is formed on the upper surface of the flange portion 6i. An electrode 6j is provided inside the flange portion 6i. A DC power source (not shown) is connected to the electrode 6j. The electrostatic chuck 6 attracts the edge ring 5 by the Coulomb force (electrostatic force) generated by applying a DC voltage from the DC power source to the electrode 6j. As a result, the edge ring 5, which is a target object, is held on the upper surface of the flange portion 6i (i.e., the upper surface of the convex portion). That is, the upper surface of the flange portion 6i (i.e., the upper surface of the convex portion) makes contact with the back surface of the edge ring 5 arranged around the wafer W, and constitutes an annular holding surface (or supporting surface) 6k for holding (or supporting) the edge ring 5. Elastic seals 75 and 76 are provided around the holding surface (or supporting surface) 6k of the electrostatic chuck 6. That is, the elastic seal 75 is arranged radially inward of the holding surface (or supporting surface) 6k so as to make contact with the back surface of the edge ring 5, and the elastic seal 76 is arranged radially outward of the holding surface (or supporting surface) 6k so as to make contact with the back surface of the edge ring 5. The elastic seals 75 and 76 come in contact with the edge ring 5 held on the holding surface (or supporting surface) 6k to seal the contact portion between the edge ring 5 and the electrostatic chuck 6. The elastic seals 75 and 76 have elasticity so as to be deformed in such a direction that the elastic seals 75 and 76 absorb the difference in thermal expansion between the edge ring 5 and the electrostatic chuck 70. As a result, it is possible to suppress the scattering of particles generated due to the rubbing between the holding surface (or supporting surface) 6k and the edge ring 5.

When the target object is one other than the substrate (wafer W), the elastic seal may be fixed not only to the side of the holding portion (or supporting portion) but also to the side of the target object. For example, in the example of FIG. 6, the elastic seal 60 may be fixed to the side of the upper top plate 16b.

According to the present disclosure in some embodiments, it is possible to suppress scattering of particles generated due to rubbing between a holding surface (or supporting surface) and a target object.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A device for supporting a substrate having a thermal expansion coefficient, comprising:
a base;
an electrostatic chuck disposed on the base and having a substrate supporting region, the electrostatic chuck having a thermal expansion coefficient different from the thermal expansion coefficient of the substrate; and
an annular elastic seal disposed on the substrate supporting region so as to make contact with the substrate supported on the substrate supporting region.

2. The device of claim 1, wherein the substrate supporting region has a circular shape in a plan view, and the annular elastic seal is arranged so as to be deformable around the substrate supporting region.

3. The device of claim 2, wherein the substrate supporting region includes a plurality of discrete supporting surfaces and a plurality of dots provided to surround the plurality of discrete supporting surfaces.

4. The device of claim 2, wherein an upper end of the annular elastic seal is arranged so as to be spaced apart from an outer surface of the substrate supporting region of the electrostatic chuck.

5. The device of claim 3, wherein the upper end of the annular elastic seal protrudes from the plurality of discrete supporting surfaces in a state in which the substrate is not held on the substrate supporting region.

6. The device of claim 3, wherein the electrostatic chuck further includes:
a protective wall configured to partially protect the annular elastic seal without making contact with the substrate in a state in which the substrate is supported on the substrate supporting region.

7. The device of claim 3, wherein the electrostatic chuck has a recess formed around the substrate supporting region, and a lower end of the annular elastic seal is accommodated in the recess.
